(19) United States
(12) Patent Application Publication
(10) Pub. No.: US 2026/0322260 A1
(43) Pub. Date: Oct. 15, 2026

(54) H-BRIDGE CHARGE PUMP TOPOLOGY TO REDUCE PHASE-LOCKED LOOP (PLL) AREA

(71) Applicant: QUALCOMM Incorporated, San Diego, CA (US)

(72) Inventors: David PALOMEQUE, Cork (IE); Robert David FROGGATT, Cork City (IE); Roi NAOR, Cork (IE)

(21) Appl. No.: 19/178,675

(22) Filed: Apr. 14, 2025

(51) Int. Cl. H02M 3/07; H02M 3/00; H03L 7/089

(52) U.S. Cl. CPC H02M 3/07; H02M 3/003; H03L 7/0891

(57) ABSTRACT

A phase-locked loop (PLL) is described. The PLL includes a charge pump. The charge pump includes a push auxiliary branch coupled between an N-voltage (Vₙ) node and a control voltage node of the charge pump. Additionally, the charge pump includes a pull auxiliary branch coupled between a P-voltage (Vₚ) node and the control voltage node of the charge pump. The push auxiliary branch is independent from the pull auxiliary branch. The PLL further includes a loop filter coupled to the control voltage node of the charge pump.

### FIELD OF THE DISCLOSURE

Aspects of the present disclosure relate to clock monitoring units of integrated circuits (ICs) and more specifically to an H-bridge charge pump topology that reduces phase-locked loop (PLL) area.

### BACKGROUND

A system-on-chip (SoC) is an integrated circuit that combines components of computer and electronic systems in a single microchip. This comprehensive integration provides ubiquitous use of SoCs for implementing mobile devices, laptops, vehicles, and other like devices. Successful operation of SoCs involves phase-locked loops (PLL) to generate the myriad of clocks to drive the various input/output (IO) subsystems in an SoC. PLLs commonly include a charge pump circuit which, together with a phase detector and a loop filter, converts a phase error to an analog voltage. A PLL charge pump generally utilizes a large capacitor to reduce an error in a generated analog voltage. This capacitor is generally implemented as a combination of a metal capacitor and a thick-oxide metal oxide semiconductor (MOS) capacitor.

Currently, process nodes continue a downward size minimization resulting in a current gate all around (GAA) field effect transistor (FET) (GAAFET) node. Unfortunately, the thick-oxide capacitors commonly utilized by analog and mixed-signal circuits within SoCs are not available at the GAAFET nodes. In particular, metal-oxide-semiconductor (MOS) capacitors implemented at the GAAFET node suffer from gate leakage due to a reduced thick-oxide layer. Additionally, compliance with reduced metal stack CMOS processes results in even lower capacitance density. In this context, a PLL charge pump, implemented without thick gate oxide devices, that occupies a reduced area, is desired.

### SUMMARY

A phase-locked loop (PLL) is described. The PLL includes a charge pump. The charge pump includes a push auxiliary branch coupled between an N-voltage (Vₙ) node and a control voltage node of the charge pump. Additionally, the charge pump includes a pull auxiliary branch coupled between a P-voltage (Vₚ) node and the control voltage node of the charge pump. The push auxiliary branch is independent from the pull auxiliary branch. The PLL further includes a loop filter coupled to the control voltage node of the charge pump.

A charge pump is described. The charge pump includes a push auxiliary branch coupled between an N-voltage (Vₙ) node and a control voltage node of the charge pump. Additionally, the charge pump includes a pull auxiliary branch coupled between a P-voltage (Vₚ) node and the control voltage node of the charge pump. The push auxiliary branch is independent from the pull auxiliary branch. The charge pump further includes a filter capacitor coupled to the control voltage node of the charge pump.

This has outlined, broadly, the features and technical advantages of the present disclosure in order that the detailed description that follows may be better understood. Additional features and advantages of the present disclosure will be described below. It should be appreciated by those skilled in the art that this present disclosure may be readily utilized as a basis for modifying or designing other structures for conducting the same purposes of the present disclosure. It should also be realized by those skilled in the art that such equivalent constructions do not depart from the teachings of the present disclosure as set forth in the appended claims. The novel features, which are believed to be characteristic of the present disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 illustrates an example implementation of a host system-on-chip (SoC), which is configured for an H-bridge charge pump topology that reduces phase-locked loop (PLL) area, in accordance with various aspects of the present disclosure.

FIG. 2 is a block diagram illustrating a hybrid analog/digital phase-locked loop (PLL) having an H-bridge charge pump topology that reduces the area consumed by the PLL, in accordance with various aspects of the present disclosure.

FIG. 3 is a block diagram further illustrating the H-bridge charge pump topology of FIG. 2, in accordance with various aspects of the present disclosure.

FIGS. 4A-4D are diagrams illustrating operation of the H-bridge charge pump topology of FIG. 2 in response to an output signal (UP/DN) of the phase/frequency detector (PFD) of FIG. 2, according to various aspects of the present disclosure.

FIGS. 5A-5C illustrate graphs showing a reduced error in the current delivered to the loop filter, as shown in FIG. 2, in accordance with various aspects of the present disclosure.

FIG. 6 is a process flow diagram illustrating a method to operate a hybrid analog/digital phase-locked loop (PLL) having an H-bridge charge pump topology, according to various aspects of the present disclosure.

FIG. 7 is a block diagram showing an exemplary wireless communications system in which a configuration of the disclosure may be advantageously employed.

FIG. 8 is a block diagram illustrating a design workstation used for circuit, layout, and logic design of an H-bridge charge pump topology that reduces phase-locked loop (PLL) area according to one configuration.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form to avoid obscuring such concepts.

As described herein, the use of the term “and/or” is intended to represent an “inclusive OR,” and the use of the term “or” is intended to represent an “exclusive OR.” As described herein, the term “exemplary” used throughout this description means “serving as an example, instance, or illustration,” and should not necessarily be construed as preferred or advantageous over other exemplary configurations. As described herein, the term “coupled” used throughout this description means “connected, whether directly or indirectly through intervening connections (e.g., a switch), electrical, mechanical, or otherwise,” and is not necessarily limited to physical connections. Additionally, the connections can be such that the objects are permanently connected or releasably connected. The connections can be through switches. As described herein, the term “proximate” used throughout this description means “adjacent, very near, next to, or close to.” As described herein, the term “on” used throughout this description means “directly on” in some configurations, and “indirectly on” in other configurations.

A system-on-chip (SoC) is an integrated circuit that combines components of computer and electronic systems in a single microchip. This comprehensive integration provides ubiquitous use of SoCs for implementing mobile devices, laptops, vehicles, and other like devices. Successful operation of SoCs involves phase-locked loops (PLL) to generate the myriad of clocks to drive the various input/output (IO) subsystems in an SoC. PLLs commonly include a charge pump circuit which, together with a phase detector and a loop filter, converts a phase error to an analog voltage.

For example, a hybrid analog/digital PLL generates an analog control voltage based on the phase difference between a reference clock and feedback clocks. This analog control voltage generation is generally performed using a phase detector, flowed by a charge pump, followed by a loop filter. Unfortunately, charge pumps suffer from many common circuit non-idealities, such as charge injection, charge sharing, transient delay etc., which ultimately lead to spurious tones at a reference clock frequency. As a result, a PLL charge pump generally utilizes a large capacitor to reduce an error in a generated analog voltage. This capacitor is generally implemented as a combination of a metal capacitor and a thick-oxide metal oxide semiconductor (MOS) capacitor.

Currently, process nodes continue a downward size minimization resulting in a current gate all around (GAA) field effect transistor (FET) (GAAFET) node. Unfortunately, newer GAAFET nodes no longer support thick-oxide MOS capacitors. In particular, the thick-oxide capacitors utilized by PLL charge pumps to prevent errors in an internally generated output voltage are not available at the newer GAAFET node. As a result, metal-oxide-semiconductor (MOS) capacitors implemented at the newer GAAFET node suffer from gate leakage due to a reduced thickness-oxide layer.

Additionally, compliance with reduced metal stack CMOS processes results in even lower capacitance density. Consequently, additional area is specified to achieve a same capacitance than in older nodes. In this context, a PLL charge pump, implemented without thick gate oxide devices, that occupies a reduced area, is desired. In particular, an H-bridge architecture that provides an alternative manner for substantially reducing charge sharing without using large capacitors, and power-hungry OP AMPS is desired. This innovation is driven by the lack of thick-oxide capacitors in GAA technology, which decreases capacitor density (more area for same capacitance value).

Various aspects of the present disclosure are directed to an H-bridge charge pump topology that reduces phase-locked loop (PLL) area. According to various aspects of the present disclosure, a charge pump is implemented in a hybrid phase-locked loop (PLL), in which the charge pump includes a first auxiliary branch and a second auxiliary branch. In some implementations, a hybrid PLL charge pump includes a push auxiliary branch coupled between an N-voltage (Vₙ) node and a control voltage node of the charge pump. Additionally, the hybrid PLL charge pump includes a pull auxiliary branch coupled between a P-voltage (Vₚ) node and the control voltage (V_{ctrl}) node of the charge pump.

In this implementation, the push auxiliary branch is independent from the pull auxiliary branch. In particular, the PUSH auxiliary branch may include an N-type MOS (NMOS) device driven by a low power operation amplifier with inputs Vₙ and V_{ctrl}. Conversely, the PULL auxiliary branch may include a P-type MOS (PMOS) device driven by a low power operation amplifier with inputs Vₚ and V_{ctrl}., which are independent from the Vₙ and V_{ctrl} inputs of the PUSH auxiliary branch. Additionally, the hybrid PLL may include a loop filter coupled to the control voltage node of the charge pump.

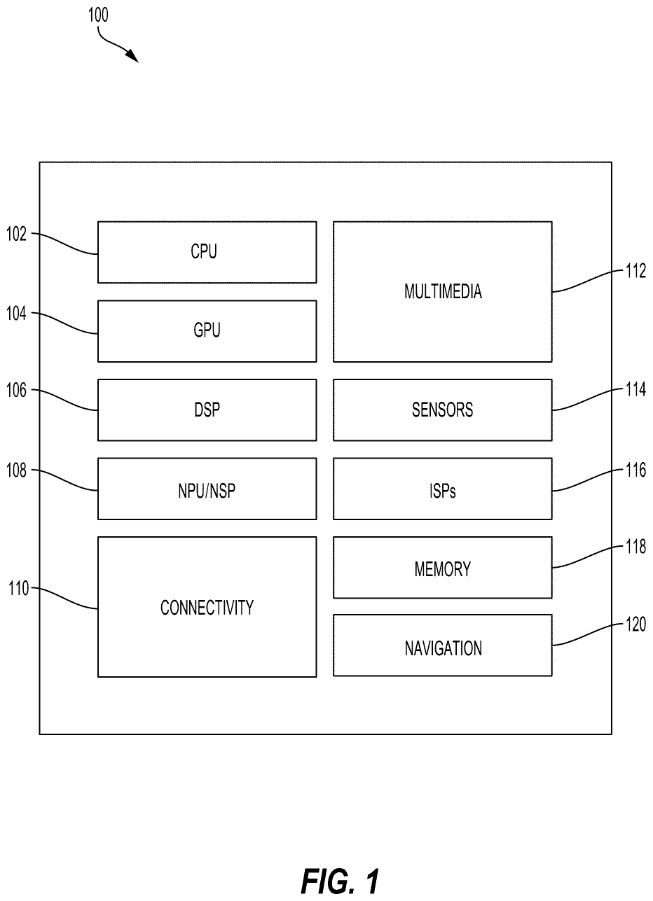

FIG. 1 illustrates an example implementation of a system-on-chip (SoC) 100, which is configured for an H-bridge charge pump topology that reduces phase-locked loop (PLL) area, in accordance with various aspects of the present disclosure. The SoC 100 includes processing blocks tailored to specific functions, such as a connectivity block 110. The connectivity block 110 may include sixth generation (6G), connectivity fifth generation (5G) new radio (NR) connectivity, fourth generation long term evolution (4G LTE) connectivity, Wi-Fi connectivity, USB connectivity, Bluetooth® connectivity, Secure Digital (SD) connectivity, and the like.

In this configuration, the SoC 100 includes various processing units that support multi-threaded operation. For the configuration shown in FIG. 1, the SoC 100 includes a multi-core central processing unit (CPU) 102, a graphics processor unit (GPU) 104, a digital signal processor (DSP) 106, and a neural processor unit (NPU)/neural signal processor (NSP) 108. The SoC 100 may also include a sensor processor 114, image signal processors (ISPs) 116, a navigation module 120, which may include a global positioning system, and a memory 118.

The multi-core CPU 102, the GPU 104, the DSP 106, the NPU/NSP 108, and the multimedia engine 112 support various functions such as video, audio, graphics, gaming, artificial networks, and the like. The SoC 100 may be based on any architecture, such as a complex instruction set (CISC) architecture, an ARM, RISC-V (RISC-five), or any reduced instruction set computing (RISC) architecture. Each processor core of the multi-core CPU 102 may be a RISC-V machine, an advanced RISC machine (ARM), a microprocessor, or some other type of processor. The NPU/NSP 108 may be based on an ARM instruction set.

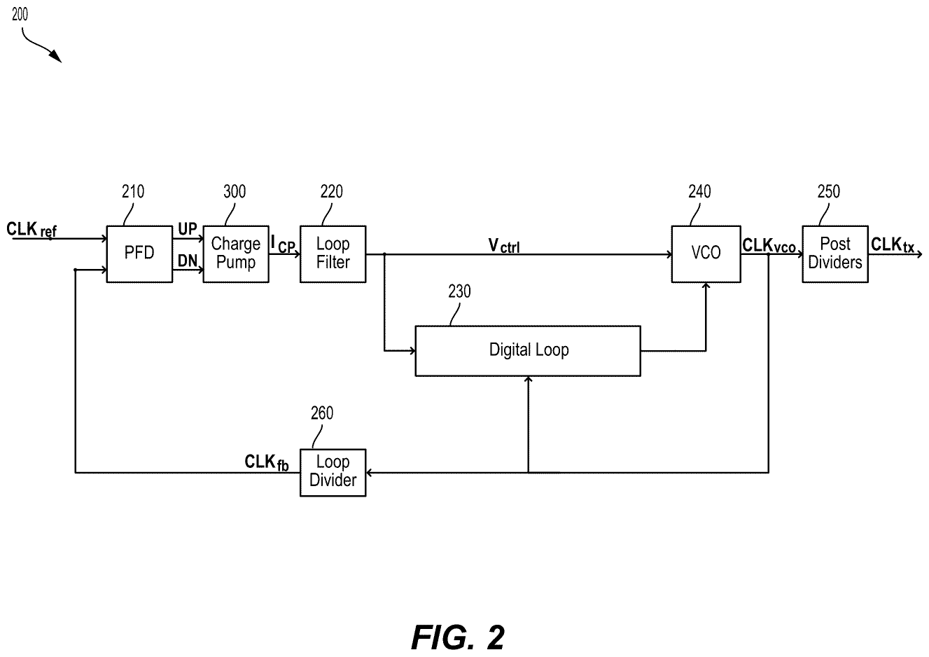

FIG. 2 is a block diagram illustrating a hybrid analog/digital phased-locked loop (PLL) 200 having an H-bridge charge pump topology that reduces phase-locked loop (PLL) area, in accordance with various aspects of the present disclosure. In practice, a phase-locked loop is a circuit that generates an output signal having a predetermined frequency and/or phase relationship with a reference signal. As shown in FIG. 2, the hybrid analog/digital PLL 200 contains a phase/frequency detector (PFD) 210 for comparing the fixed frequency signal (reference clock signal CLK_{ref}) with a feedback signal (clock feedback CLK_{fb}) output by a loop divider 260 that is located in a feedback loop. In this example, the PFD 210 is coupled to a charge pump 300. The PFD 210 outputs a signal (UP/DN) to the charge pump 300 that is representative of the phase and/or frequency difference between the clock feedback signal (CLK_{fb}) and the reference clock signal (CLK_{ref}).

The charge pump 300 injects a current (I_{cp}) to a loop filter 220 in response to the signal (UP/DN) received from the PFD 210. In some implementations, the loop filter 220 can be implemented using a filter capacitor C coupled between the output of the charge pump 300 and ground. This current injection may take the form of either an “up” or “down” current. In other words, the PFD 210 and the charge pump 300 work together for output of either positive or negative current “pulses” in response to whether the reference clock signal's phase leads or lags the clock feedback signal (CLK_{fb}). The loop filter 220 filters these charge pulses to generate a voltage control signal (V_{ctrl}) for a voltage-controlled oscillator (VCO) 240 controlled by a tuning voltage at its control input. The loop filter 220 may be arranged to integrate the current pulses received from the charge pump to generate the tuning voltage for controlling the VCO 240. If the clock feedback signal (CLK_{fb}) lags the reference clock signal (CLK_{ref}), the VCO 240 speeds up. Conversely, if the clock feedback signal (CLK_{fb}) leads the reference clock signal (CLK_{ref}), the VCO 240 slows down, outputting a VCO clock signal (CLK_{vco}). Additionally, a post divider 250 to provide an output clock signal (CLKₜₓ), and a control voltage is provided from the loop filter 220 to a digital loop 230.

Implementation of the hybrid analog/digital PLL 200 in a current process node may involve a redesign of the charge pump 300, which works with the PFD 210 and the loop filter 220 to provide an analog voltage control signal (V_{ctrl}). For example, the charge pump 300 may be initially designed based on a conventional H-bridge topology, which operates based on a tradeoff between charge pump current and capacitor area. Current process nodes, however, continue a downward size minimization resulting in a current gate all around (GAA) field effect transistor (FET) (GAAFET) node.

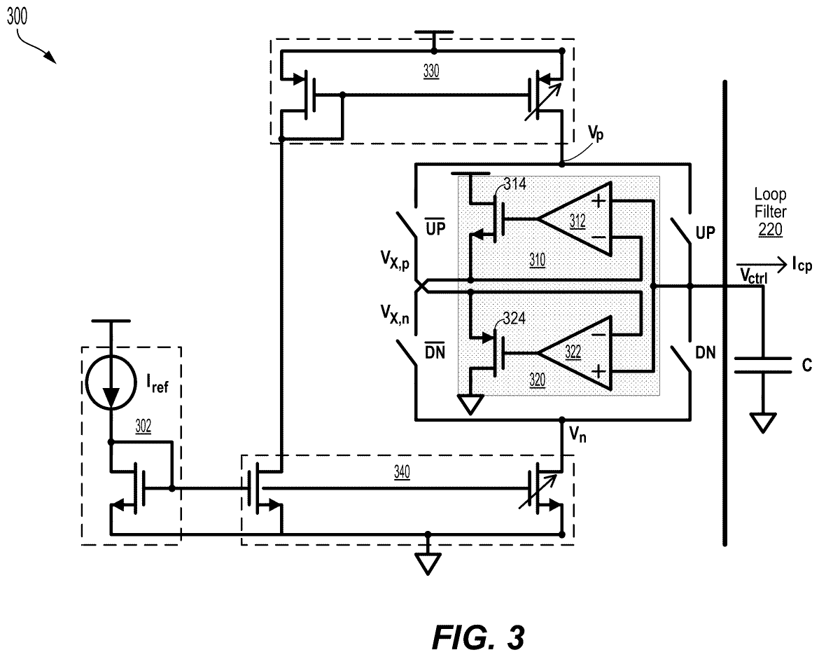

Unfortunately, newer GAAFET nodes no longer support thick-oxide MOS capacitors. In particular, the thick-oxide capacitors utilized by PLL charge pumps to prevent errors in an internally generated output voltage are not available at the newer GAAFET node. As a result, metal-oxide-semiconductor (MOS) capacitors implemented at the newer GAAFET node suffer from gate leakage due to a reduced thickness-oxide layer. In this context, an H-bridge architecture for providing an alternative manner for substantially reducing charge sharing without using large capacitors, and power-hungry OP AMPS is desired. This innovation is driven by the lack of thick-oxide capacitors in GAA technology, which decreases capacitor density (more area for same capacitance value). A proposed H-bridge charge pump topology that reduces phase-locked loop (PLL) area is shown, for example, in FIG. 3.

FIG. 3 is a block diagram further illustrating the charge pump 300 of FIG. 2, in accordance with various aspects of the present disclosure. As shown in FIG. 3, the charge pump 300 based on an H-bridge charge pump topology that reduces PLL area and may be implemented in the hybrid analog/digital PLL 200 of FIG. 2. Although illustrated with reference to the hybrid analog/digital PLL 200 of FIG. 2, it should be recognized that the charge pump 300 may be implemented in analog PLL circuits or other like timing circuits.

As shown in FIG. 3, the charge pump 300 includes a first auxiliary branch and a second auxiliary branch for maintaining a balance between a P-voltage (Vₚ) node and an N-voltage (Vₙ) node. A reference current source (I_{ref}) 302 supplies a Vₚ current source 330 and a Vₙ current source 340. In this implementation, the charge pump 300 includes a push auxiliary branch 310 coupled between the Vₚ node and a VCO control voltage (V_{ctrl}) node of the charge pump 300. Additionally, the charge pump 300 includes a pull auxiliary branch 320 coupled between the Vₙ node and the V_{ctrl} node of the charge pump 300. In this implementation, the push auxiliary branch 310 is independent from the pull auxiliary branch 320. Additionally, the loop filter 220 is shown as coupled to the V_{ctrl} node of the charge pump 300.

In this example, the push auxiliary branch 310 includes an operational amplifier 312 having a first input terminal (+) coupled to the V_{ctrl} node of the charge pump 300 and a second input terminal (−) coupled to the Vₙ node. Additionally, the push auxiliary branch 310 includes a transistor 314 having a gate coupled to an output terminal of the operational amplifier 312. Additionally, a source of the transistor 314 is coupled to the Vₙ node through a DN-bar switch to provide a node voltage (V_{X,n}) when the DN-bar switch is closed. In this example, the transistor 314 is configured as an N-type metal oxide semiconductor (NMOS) device and the source of the NMOS device is coupled to the second input terminal (−).

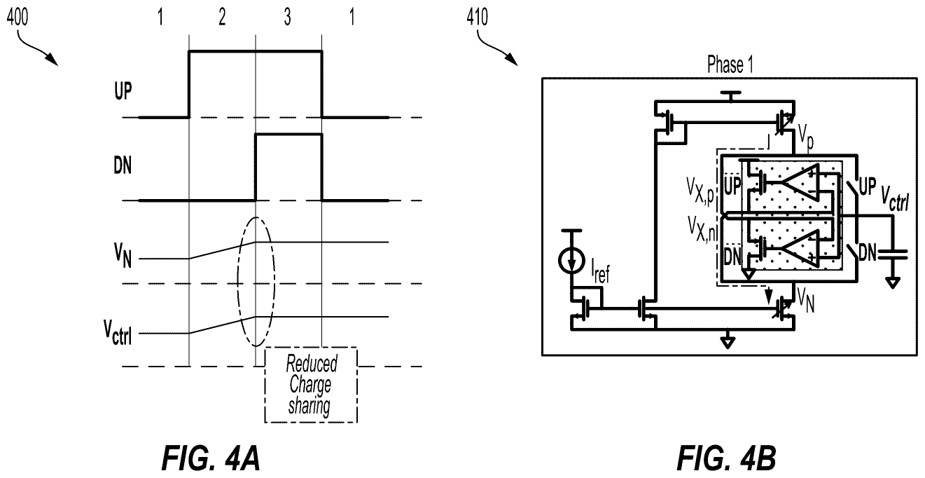

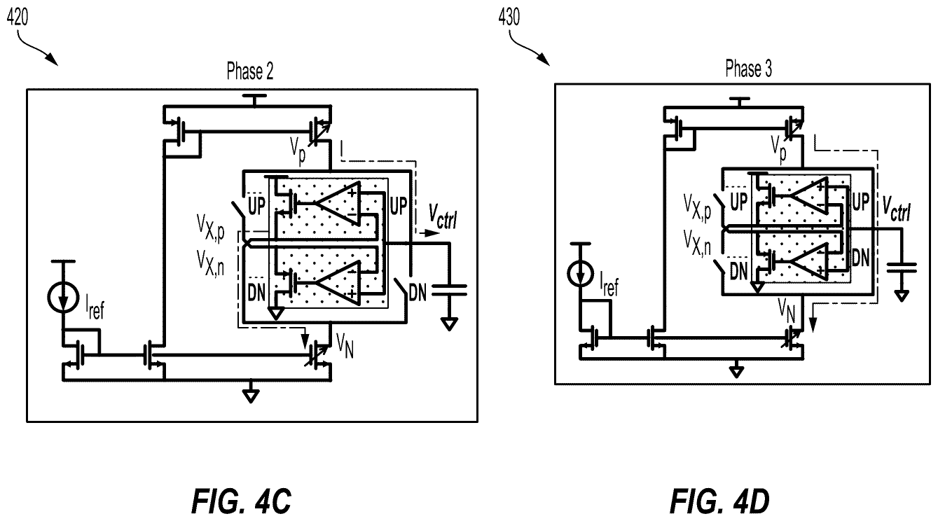

As further illustrated in FIG. 3, the pull auxiliary branch 320 includes an operational amplifier 322 having a first input terminal (+) coupled to the V_{ctrl} node of the charge pump 300 and a second input terminal (−) coupled to the Vₚ node. Additionally, the pull auxiliary branch 320 includes a transistor 324 having a gate coupled to an output terminal of the operational amplifier 322. A source of the transistor 324 is coupled to the Vₚ node through an UP-bar switch to provide a node voltage (V_{X,p}) when the UP-bar switch is closed. In this example, the transistor 324 is configured as a P-type metal oxide semiconductor (PMOS) device and the source of the PMOS device is coupled to the second input terminal (−). In this implementation, operation of the charge pump is further controlled by an UP switch coupled between the Vₚ node and the V_{ctrl} node of the charge pump 300 and a DN switch coupled between the V_{ctrl} node of the charge pump 300 and the Vₚ node, as further illustrated in FIGS. 4A-4D.

FIGS. 4A-4D are diagrams illustrating operation of the charge pump 300 in response to an output signal (UP/DN) of the PFD 210 of FIG. 2, according to various aspects of the present disclosure. FIG. 4A illustrates a timing diagram 400 showing three phases of the output signal (UP/DN) of the PFD 210 of FIG. 2, which controls opening and closing of the switches (e.g., UP, UP-bar, DN, DN-bar) of the charge pump 300 during an UP pulse from the PFD 210.

FIG. 4B illustrates the charge pump 300 during a first phase 410 of the timing diagram 400. During the first phase 410 of the timing diagram 400, the UP signal and the DN signal are inactive, triggering the UP-bar switch (e.g., a first switch) and the DN-bar switch (e.g., a second switch) to close. Additionally, the inactive UP and DN signals trigger the UP switch and the DN switch to open. During the first phase 410, neither the push auxiliary branch 310 nor the pull auxiliary branch 320 are sinking or sourcing current.

FIG. 4C illustrates the charge pump 300 during a second phase 420 of the timing diagram 400. During the second phase 420 of the timing diagram 400, the UP signal is active and the DN signals remains inactive, triggering the UP switch to close and maintain the DN switch open. Additionally, the active UP signal and the inactive DN signals trigger the UP-bar switch to open and the DN-bar switch to remain closed. During the second phase 420, the push auxiliary branch 310 sources current to the Vₙ to match the current sinking at the V_{ctrl} node.

FIG. 4D illustrates the charge pump 300 during a third phase 430 of the timing diagram 400. During the third phase 430 of the timing diagram 400, the UP signal and the DN signal are active, triggering the DN switch to close and maintain the UP switch closed. Additionally, the active UP signal and the active DN signal trigger the DN-bar switch to open and the UP-bar switch to remain open. During the second phase 420, the push auxiliary branch 310 sources current to the Vₙ to match the current sinking at the V_{ctrl} node. During the third phase 430 of the timing diagram 400, neither the push auxiliary branch 310 nor the pull auxiliary branch 320 are sinking or sourcing current.

Referring again to FIG. 4A, the timing diagram 400 further illustrates a Vₙ signal and a V_{ctrl} signal, which exhibit a reduced charge sharing by utilizing the first auxiliary branch (e.g., a push auxiliary branch 310) and the second auxiliary branch (e.g., a pull auxiliary branch 320) for maintaining a balance between the Vₚ node and the Vₙ node. This balance enables the source current during the second phase 420 to track the current sinking at the V_{ctrl} node of the charge pump 300 with the current sourcing to the Vₙ node for reduced charge sharing. Additionally, this configuration of the push auxiliary branch 310 and the pull auxiliary branch 320 utilizes low-power configurations of the operational amplifier 312 and the operational amplifier 322 to consume a smaller area.

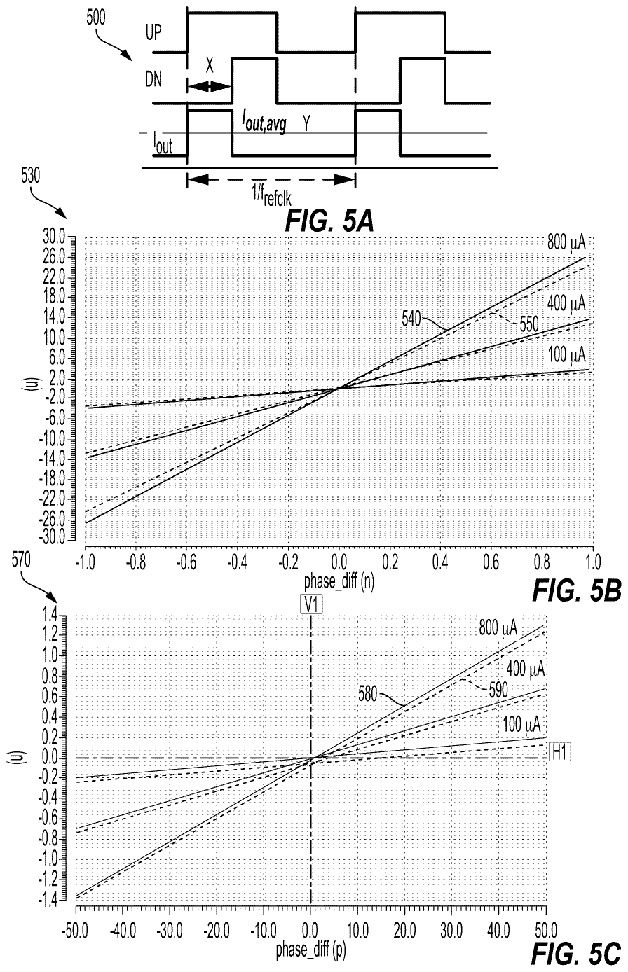

FIGS. 5A-5C illustrate graphs showing a reduced error in the current delivered to the loop filter 220, as shown in FIG. 2, in accordance with various aspects of the present disclosure. FIG. 5A illustrates a timing diagram 500 of UP and DN signals as well as an output current (Iₒᵤₜ). In the examples of FIGS. 5B and 5C, an X-axis (nanoseconds (ns)) represents a phase difference between the UP and DN signals, and a Y-axis (microamps (μA)) represents an average of the output current I_{out, avg}. FIG. 5B illustrates a positive phase difference (phase_diff (p)) versus output current I_{out, avg} graph 530 showing a proposed solution 540 and a conventional solution 550 for various output currents (e.g., 100 μA, 400 μA, and 800 μA). Additionally, FIG. 5C illustrates a negative phase difference (phase_diff (n)) verses output current I_{out, avg} graph 570 at the Vₚ node showing a proposed solution 580 and the conventional solution 590 for various output currents (e.g., 100 μA, 400 μA, and 800 μA).

According to various aspects of the present disclosure, the proposed solution achieves a smaller error both for large phase differences (during locking) and very small phase differences (after locking). Additionally, the disclosed charge pump configuration achieves lower current consumption for low and moderate output currents of the charge pump 300, which exhibits a reduced error in the current delivered to the loop filter 220, as shown in FIG. 2. The configuration of the charge pump 300 eliminates the use of large branch capacitors as well as reduced size operational amplifiers (OpAmps), providing substantial savings (e.g., 25%).

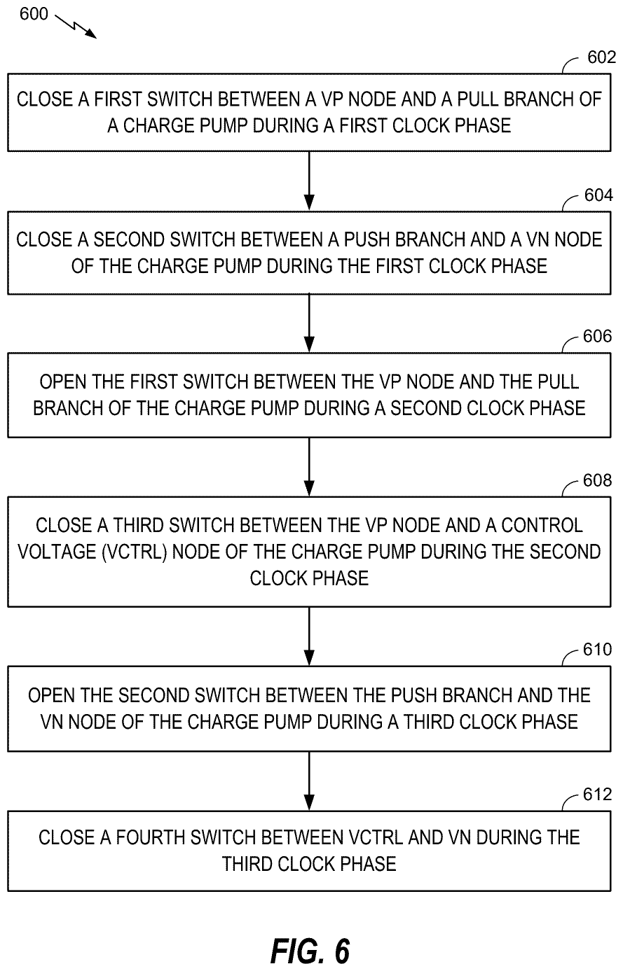

FIG. 6 is a process flow diagram illustrating a method 600 to operate a hybrid analog/digital phase-locked loop (PLL) charge pump during an, according to various aspects of the present disclosure. FIG. 6 illustrates operation of, for example, the charge pump 300 in response to an UP-output signal from the PFD 210 outputs, as shown in FIGS. 2 and 3.

The method 600 begins at block 602, in which a first switch between a Vₚ node and a pull branch of a charge pump is closed during a first clock phase. At block 604, a second switch between a push branch and a Vₙ node of the charge pump is closed during the first clock phase. For example, as shown in FIGS. 4A and 4B, during the first phase 410 of the timing diagram 400, the UP signal and the DN signal are inactive, triggering the UP-bar switch (e.g., a first switch) and the DN-bar switch (e.g., a second switch) of the charge pump 300 to close. Additionally, the inactive UP and DN signals trigger the UP switch and the DN switch to open. During the first phase 410, neither the push auxiliary branch 310 nor the pull auxiliary branch 320 are sinking or sourcing current.

At block 606, the first switch between the Vₚ node and the pull branch of the charge pump is opened during a second clock phase. At block 608, a third switch between the Vₚ node and a control voltage (V_{ctrl}) node of the charge pump is closed during the second clock phase. For example, as shown in FIGS. 4A and 4C, during the second phase 420 of the timing diagram 400, the UP signal is active and the DN signals remains inactive, triggering the UP switch to close and maintain the DN switch open. Additionally, the active UP signal and the inactive DN signals trigger the UP-bar switch to open and the DN-bar switch to remain closed. During the second phase 420, the push auxiliary branch 310 sources current to the Vₙ to match the current sinking at the V_{ctrl} node.

At block 610, the second switch between the push branch and the Vₙ node of the charge pump is opened during a third clock phase. At block 612, a fourth switch between V_{ctrl} and Vₙ is closed during the third clock phase. For example, as shown in FIGS. 4A and 4D, during the third phase 430 of the timing diagram 400, the UP signal and the DN signal are active, triggering the DN switch to close and maintain the UP switch closed. Additionally, the active UP signal and the active DN signal trigger the DN-bar switch to open and the UP-bar switch to remain open. During the second phase 420, the push auxiliary branch 310 sources current to the Vₙ to match the current sinking at the V_{ctrl} node. During the third phase 430 of the timing diagram 400, neither the push auxiliary branch 310 nor the pull auxiliary branch 320 are sinking or sourcing current.

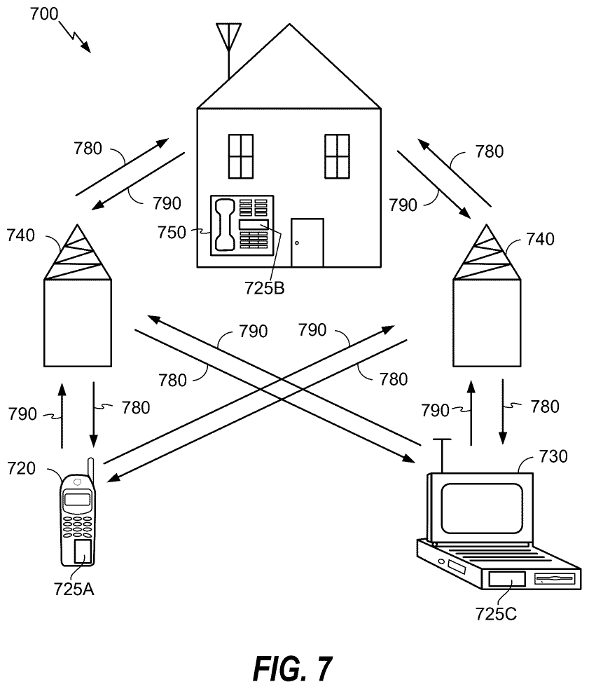

FIG. 7 is a block diagram showing an exemplary wireless communications system 700 in which an aspect of the present disclosure may be advantageously employed. For purposes of illustration, FIG. 7 shows three remote units 720, 730, and 750 and two base stations 740. It will be recognized that wireless communications systems may have many more remote units and base stations. Remote units 720, 730, and 750 include integrated circuit (IC) devices 725A, 725C, and 725B that include the disclosed the hybrid PLL charge pump. It will be recognized that other devices may also include the high voltage power switch, such as the base stations 740, switching devices, and network equipment. FIG. 7 shows forward link signals 780 from the base stations 740 to the remote units 720, 730, and 750, and reverse link signals 790 from the remote units 720, 730, and 750 to the base stations 740.

In FIG. 7, remote unit 720 is shown as a mobile telephone, remote unit 730 is shown as a portable computer, and remote unit 750 is shown as a fixed location remote unit in a high voltage power switch system. For example, the remote units may be a mobile phone, a hand-held personal communication systems (PCS) unit, a portable data unit, such as a personal data assistant, a GPS enabled device, a navigation device, a set top box, a music player, a video player, an entertainment unit, a communications device, personal digital assistant (PDA), a fixed location data unit, such as meter reading equipment, or other device that stores or retrieves data or computer instructions, or combinations thereof. Although FIG. 7 illustrates remote units according to the aspects of the present disclosure, the present disclosure is not limited to these exemplary illustrated units. Aspects of the present disclosure may be suitably employed in many devices, which include the disclosed the hybrid PLL charge pump.

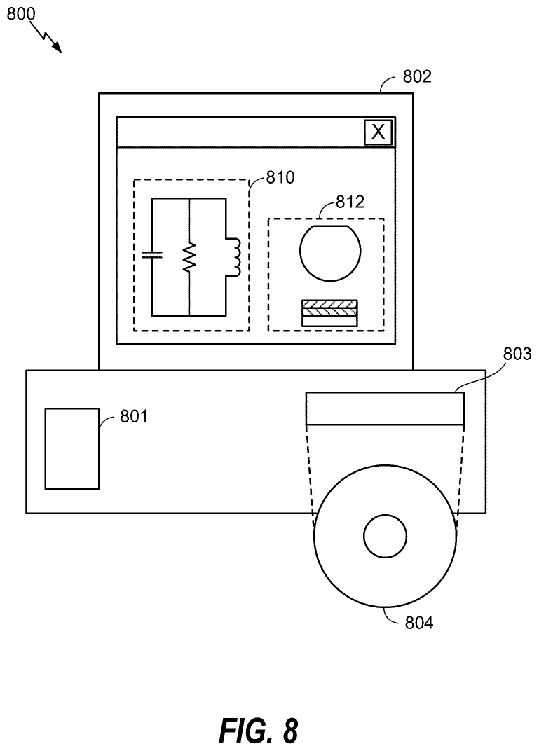

FIG. 8 is a block diagram illustrating a design workstation used for circuit, layout, and logic design of a semiconductor component, such as the high voltage power switch disclosed above. A design workstation 800 includes a hard disk 801 containing operating system software, support files, and design software such as Cadence or OrCAD. The design workstation 800 also includes a display 802 to facilitate design of a circuit 810, such as a high voltage power switch. A storage medium 804 is provided for tangibly storing the design of the circuit 810 (e.g., the hybrid PLL charge pump). The design of the circuit 810 or a hybrid PLL charge pump 812 may be stored on the storage medium 804 in a file format such as GDSII or GERBER. The storage medium 804 may be a compact disc read-only memory (CD-ROM), digital versatile disc (DVD), hard disk, flash memory, or another appropriate device. Furthermore, the design workstation 800 includes a drive apparatus 803 for accepting input from or writing output to the storage medium 804.

Data recorded on the storage medium 804 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 804 facilitates the design of the circuit 810 or the hybrid PLL charge pump 812 by decreasing the number of processes for designing semiconductor wafers.

Implementation examples are described in the following numbered clauses:
1. A phase-locked loop (PLL), comprising:
a charge pump comprising:
   a push auxiliary branch coupled between an N-voltage (Vₙ) node and a control voltage node of the charge pump, and
   a pull auxiliary branch coupled between a P-voltage (Vₚ) node and the control voltage node of the charge pump, in which the push auxiliary branch is independent from the pull auxiliary branch; and
a loop filter coupled to the control voltage node of the charge pump.
2. The PLL of clause 1, in which the push auxiliary branch comprises:
an operational amplifier having a first input terminal coupled to the control voltage node of the charge pump and a second input terminal coupled to the Vₙ node; and
a transistor having a gate coupled to an output terminal of the operational amplifier and a source coupled to the Vₙ node.
3. The PLL of clause 2, further comprising a switch coupled between the source of the transistor and the Vₙ node.
4. The PLL of clause 2, in which the transistor comprises an N-type metal oxide semiconductor (NMOS) device.
5. The PLL of clause 2, in which the second input terminal of the operational amplifier is coupled to the source of the transistor.
6. The PLL of any of clauses 1-5, in which the pull auxiliary branch comprises:
an operational amplifier having a first input terminal coupled to the control voltage node of the charge pump and a second input terminal coupled to the Vₚ node; and
a transistor having a gate coupled to an output terminal of the operational amplifier and a source coupled to the Vₚ node.
7. The PLL of clause 6, further comprising a switch coupled between the source of the transistor and the Vₚ node.
8. The PLL of clause 6, in which the transistor comprises a P-type metal oxide semiconductor (PMOS) device.
9. The PLL of clause 6, in which the second input terminal of the operational amplifier is coupled to the source of the transistor.
10. The PLL of any of clauses 1-9, further comprising:
a first switch coupled between the Vₚ node and the control voltage node of the charge pump; and
a second switch coupled between the control voltage node of the charge pump and the Vₚ node.
11. A charge pump, comprising:
a push auxiliary branch coupled between an N-voltage (Vₙ) node and a control voltage node of the charge pump;
a pull auxiliary branch coupled between a P-voltage (Vₚ) node and the control voltage node of the charge pump, in which the push auxiliary branch is independent from the pull auxiliary branch; and
a filter capacitor coupled to the control voltage node of the charge pump.
12. The charge pump of clause 11, in which the push auxiliary branch comprises:
an operational amplifier having a first input terminal coupled to the control voltage node of the charge pump and a second input terminal coupled to the Vₙ node; and
a transistor having a gate coupled to an output terminal of the operational amplifier and a source coupled to the Vₙ node.
13. The charge pump of clause 12, further comprising a switch coupled between the source of the transistor and the Vₙ node.
14. The charge pump of clause 12, in which the transistor comprises an N-type metal oxide semiconductor (NMOS) device.
15. The charge pump of clause 12, in which the second input terminal of the operational amplifier is coupled to the source of the transistor.
16. The charge pump of any of clauses 11-15, in which the pull auxiliary branch comprises:
an operational amplifier having a first input terminal coupled to the control voltage node of the charge pump and a second input terminal coupled to the Vₚ node; and
a transistor having a gate coupled to an output terminal of the operational amplifier and a source coupled to the Vₚ node.
17. The charge pump of clause 16, further comprising a switch coupled between the source of the transistor and the Vₚ node.
18. The charge pump of clause 16, in which the transistor comprises a P-type metal oxide semiconductor (PMOS) device.
19. The charge pump of clause 16, in which the second input terminal of the operational amplifier is coupled to the source of the transistor.
20. The charge pump of any of clauses 11-19, further comprising:
a first switch coupled between the Vₚ node and the control voltage node of the charge pump; and
a second switch coupled between the control voltage node of the charge pump and the Vₚ node.

For a firmware and/or software implementation, the methodologies may be implemented with modules (e.g., procedures, functions, and so on) that perform the functions described herein. A machine-readable medium tangibly embodying instructions may be used in implementing the methodologies described herein. For example, software codes may be stored in a memory and executed by a processor unit. Memory may be implemented within the processor unit or external to the processor unit. As used herein, the term “memory” refers to types of long term, short term, volatile, nonvolatile, or other memory and is not limited to a particular type of memory or number of memories, or type of media upon which memory is stored.

If implemented in firmware and/or software, the functions may be stored as one or more instructions or code on a non-transitory computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include random access memory (RAM), read-only memory (ROM), electrically erasable programmable read-only memory (EEPROM), compact disc read-only memory (CD-ROM) or other optical disk storage, magnetic disk storage or other magnetic storage devices, or other medium that can be used to store desired program code in the form of instructions or data structures and that can be accessed by a computer. Disk and disc, as used herein, include compact disc (CD), laser disc, optical disc, digital versatile disc (DVD), floppy disk and Blu-ray® disc, where disks usually reproduce data magnetically, while discs reproduce data optically with lasers. Combinations of the above should also be included within the scope of computer-readable media.

In addition to storage on computer-readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although the present disclosure and its advantages have been described in detail, various changes, substitutions, and alterations can be made herein without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above, and below may refer to sides of a substrate or electronic device. Moreover, the scope of the present application is not intended to be limited to the configurations of the process, machine, manufacture, composition of matter, means, methods, and steps described in the specification. As one of ordinary skill in the art will readily appreciate from the disclosure, processes, machines, manufacture, compositions of matter, means, methods, or steps, presently existing or later to be developed that perform substantially the same function, or achieve substantially the same result as the corresponding configurations described herein, may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the application and design constraints imposed on the overall system. Skilled artisans may implement the described functionality in varying ways for each application, but such implementation decisions should not be interpreted as causing a departure from the scope of the present disclosure.

The various illustrative logical blocks, modules, and circuits described in connection with the disclosure herein may be implemented or performed with a general-purpose processor, a digital signal processor (DSP), an application-specific integrated circuit (ASIC), a field-programmable gate array (FPGA) or other programmable logic device, discrete gate or transistor logic, discrete hardware components, or any combination thereof designed to perform the functions described herein. A general-purpose processor may be a microprocessor, but, in the alternative, the processor may be any conventional processor, controller, microcontroller, or state machine. A processor may also be implemented as a combination of computing devices, e.g., a combination of a DSP and a microprocessor, multiple microprocessors, one or more microprocessors in conjunction with a DSP core, or any other such configuration.

The steps of a method or algorithm described in connection with the present disclosure may be embodied directly in hardware, in a software module executed by a processor, or in a combination of the two. A software module may reside in random access memory (RAM), flash memory, read-only memory (ROM), erasable programmable read-only memory (EPROM), electrically erasable programmable read-only memory (EEPROM), registers, hard disk, a removable disk, a compact disc read-only memory (CD-ROM), or any other form of storage medium known in the art. An exemplary storage medium is coupled to the processor such that the processor can read information from, and write information to, the storage medium. In the alternative, the storage medium may be integral to the processor. The processor and the storage medium may reside in an application-specific integrated circuit (ASIC). The ASIC may reside in a user terminal. In the alternative, the processor and the storage medium may reside as discrete components in a user terminal.

In one or more exemplary designs, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general-purpose or special-purpose computer. By way of example, and not limitation, such computer-readable media can include random access memory (RAM), read-only memory (ROM), electrically erasable programmable read-only memory (EEPROM), compact disc read-only memory (CD-ROM) or other optical disk storage, magnetic disk storage or other magnetic storage devices, or any other medium that can be used to carry or store specified program code means in the form of instructions or data structures and that can be accessed by a general-purpose or special-purpose computer, or a general-purpose or special-purpose processor. In addition, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include compact disc (CD), laser disc, optical disc, digital versatile disc (DVD), floppy disk, and Blu-ray® disc, where disks usually reproduce data magnetically, while discs reproduce data optically with lasers. Combinations of the above should also be included within the scope of computer-readable media.

The previous description of the present disclosure is provided to enable any person skilled in the art to make or use the disclosure. Various modifications to the present disclosure will be readily apparent to those skilled in the art, and the generic principles defined herein may be applied to other variations without departing from the spirit or scope of the disclosure. Thus, the present disclosure is not intended to be limited to the examples and designs described herein but is to be accorded the widest scope consistent with the principles and novel features disclosed herein.

What is claimed:

1. A phase-locked loop (PLL), comprising:
a charge pump comprising:
a push auxiliary branch coupled between an N-voltage (Vₙ) node and a control voltage node of the charge pump, and
a pull auxiliary branch coupled between a P-voltage (Vₚ) node and the control voltage node of the charge pump, in which the push auxiliary branch is independent from the pull auxiliary branch; and
a loop filter coupled to the control voltage node of the charge pump.

2. The PLL of claim 1, in which the push auxiliary branch comprises:
an operational amplifier having a first input terminal coupled to the control voltage node of the charge pump and a second input terminal coupled to the Vₙ node; and
a transistor having a gate coupled to an output terminal of the operational amplifier and a source coupled to the Vₙ node.

3. The PLL of claim 2, further comprising a switch coupled between the source of the transistor and the Vₙ node.

4. The PLL of claim 2, in which the transistor comprises an N-type metal oxide semiconductor (NMOS) device.

5. The PLL of claim 2, in which the second input terminal of the operational amplifier is coupled to the source of the transistor.

6. The PLL of claim 1, in which the pull auxiliary branch comprises:
an operational amplifier having a first input terminal coupled to the control voltage node of the charge pump and a second input terminal coupled to the Vₚ node; and
a transistor having a gate coupled to an output terminal of the operational amplifier and a source coupled to the Vₚ node.

7. The PLL of claim 6, further comprising a switch coupled between the source of the transistor and the Vₚ node.

8. The PLL of claim 6, in which the transistor comprises a P-type metal oxide semiconductor (PMOS) device.

9. The PLL of claim 6, in which the second input terminal of the operational amplifier is coupled to the source of the transistor.

10. The PLL of claim 1, further comprising:
a first switch coupled between the Vₚ node and the control voltage node of the charge pump; and
a second switch coupled between the control voltage node of the charge pump and the Vₚ node.

11. A charge pump, comprising:
a push auxiliary branch coupled between an N-voltage (Vₙ) node and a control voltage node of the charge pump;
a pull auxiliary branch coupled between a P-voltage (Vₚ) node and the control voltage node of the charge pump, in which the push auxiliary branch is independent from the pull auxiliary branch; and
a filter capacitor coupled to the control voltage node of the charge pump.

12. The charge pump of claim 11, in which the push auxiliary branch comprises:
an operational amplifier having a first input terminal coupled to the control voltage node of the charge pump and a second input terminal coupled to the Vₙ node; and
a transistor having a gate coupled to an output terminal of the operational amplifier and a source coupled to the Vₙ node.

13. The charge pump of claim 12, further comprising a switch coupled between the source of the transistor and the Vₙ node.

14. The charge pump of claim 12, in which the transistor comprises an N-type metal oxide semiconductor (NMOS) device.

15. The charge pump of claim 12, in which the second input terminal of the operational amplifier is coupled to the source of the transistor.

16. The charge pump of claim 11, in which the pull auxiliary branch comprises:
an operational amplifier having a first input terminal coupled to the control voltage node of the charge pump and a second input terminal coupled to the Vₚ node; and
a transistor having a gate coupled to an output terminal of the operational amplifier and a source coupled to the Vₚ node.

17. The charge pump of claim 16, further comprising a switch coupled between the source of the transistor and the Vₚ node.

18. The charge pump of claim 16, in which the transistor comprises a P-type metal oxide semiconductor (PMOS) device.

19. The charge pump of claim 16, in which the second input terminal of the operational amplifier is coupled to the source of the transistor.

20. The charge pump of claim 11, further comprising:
a first switch coupled between the Vₚ node and the control voltage node of the charge pump; and
a second switch coupled between the control voltage node of the charge pump and the Vₚ node.
